(19) United States
(12) Patent Application Publication
(10) Pub. No.: US 2024/0266367 A1
(43) Pub. Date: Aug. 8, 2024

(54) ARRAY SUBSTRATE, MANUFACTURING METHOD THEREOF, AND DISPLAY APPARATUS

(71) Applicants: Ordos Yuansheng Optoelectronics Co., Ltd., Ordos, Inner Mongolia (CN); BOE TECHNOLOGY GROUP CO., LTD., Beijing (CN)

(72) Inventors: Yongqiang ZHANG, Beijing (CN); Jian SUN, Beijing (CN); Jingyi XU, Beijing (CN); Aiyu DING, Beijing (CN); Feng LI, Beijing (CN); Lei YAO, Beijing (CN)

(21) Appl. No.: 18/021,197

(22) PCT Filed: May 27, 2022
(86) PCT No.: PCT/CN2022/095556

§ 371 Date: Feb. 14, 2023

(51) Int. Cl. H01L 27/12

(52) U.S. Cl. CPC H01L 27/1251; H01L 27/1225; H01L 27/127

(57) ABSTRACT

An array substrate includes a display area and a peripheral area on a side of the display area, and includes a base substrate, at least one low temperature polycrystalline silicon thin film transistor on the base substrate and in the peripheral area, and at least one oxide thin film transistor on the base substrate and in the display area; the low temperature polycrystalline silicon thin film transistor includes a low temperature polycrystalline silicon semiconductor layer, a first gate, and a first source and a first drain, which are sequentially arranged along a direction away from the base substrate; the oxide thin film transistor includes an oxide semiconductor layer, a second gate, and a second source and a second drain, which are sequentially arranged along the direction away from the base substrate; and the first source and the first drain are each in a different layer from the second gate.

### TECHNICAL FIELD

The present disclosure belongs to the technical field of display, and particularly relates to an array substrate, a manufacturing method thereof, and a display apparatus.

### BACKGROUND

With the continuous development of display technologies, users have higher and higher requirements on a pixel resolution of display apparatuses, and the display apparatuses, such as a Virtual Reality (VR) display apparatus and an Augmented Reality (AR) display apparatus, have a pixel resolution exceeding 2000 PPI (Pixels Per Inch). In order to ensure that the leakage current (Ioff) of a thin film transistor in the conventional Low Temperature Polysilicon (LTPS) technology is low enough, the Thin Film Transistor (TFT) in the array substrate is required to be made into a double-gate structure, which occupies a large space and cannot meet the requirements on high resolution. The TFT may be formed into a single-gate structure in Oxide material (Oxide) technology, but the on-state current (Ion) thereon is low, which cannot meet the requirements on a circuit in the peripheral area. Therefore, Low Temperature Polycrystalline Oxide (LTPO), which can not only ensure a low leakage current and a high on-state current, but also ensure a small space occupied, came into being, and has become the mainstream design of VR and AR display products at present.

The LTPO technology is a combination of technologies of LTPS and Oxide material (Oxide), LTPS TFTs are used in the circuits in the peripheral area of the array substrate, and Oxide TFTs are used in the circuits in the display area. However, the source and drain of the LTPS TFT in the peripheral area of the array substrate adopting the LTPO technology are generally arranged in a same layer as the gate of the Oxide TFT in the display area. If the source and drain of the LTPS TFT and the gate of the Oxide TFT are all made of a metal with a small slope angle, such as molybdenum (Mo), the sheet resistance thereof is large, so that the resistance of wiring in the peripheral area is large, which is prone to cause a problem of distortion of a display image due to signal delay. If the source and the drain of the LTPS TFT and the gate of the Oxide TFT are all made of a metal with a small sheet resistance, such as a three-layer structure composed of titanium/aluminum/titanium (Ti/Al/Ti) alloy, the slope angle thereof is large, so that a trench is prone to be formed near the gate of the Oxide TFT, and when the drain of the Oxide TFT is formed, a metal of adjacent drains is prone to remain at the position of the trench, which causes a short circuit occurring between the drains in the adjacent Oxide TFTs, thereby affecting the display performance.

### SUMMARY

The present disclosure aims to solve at least one technical problem in the prior art and provides an array substrate, a manufacturing method thereof, and a display apparatus.

In a first aspect, an embodiment of the present disclosure provides an array substrate, including a display area and a peripheral area on a side of the display area, where the array substrate includes a base substrate, at least one low temperature polycrystalline silicon thin film transistor on the base substrate and in the peripheral area, and at least one oxide thin film transistor on the base substrate and in the display area;
each of the at least one low temperature polycrystalline silicon thin film transistor includes a low temperature polycrystalline silicon semiconductor layer, a first gate, and a first source and a first drain, which are sequentially arranged along a direction away from the base substrate;
each of the at least one oxide thin film transistor includes an oxide semiconductor layer, a second gate, and a second source and a second drain, which are sequentially arranged along the direction away from the base substrate; and
the first source and the first drain are each in a different layer from the second gate.

Optionally, the first source and the first drain are each in a same layer as the second drain.

Optionally, the second source and the second drain are in different layers, respectively.

Optionally, the second source is on a side of the second drain away from the base substrate.

Optionally, the array substrate further includes a pixel electrode; and
the pixel electrode is on a side of the second source away from the base substrate, and is electrically connected to the second source.

Optionally, the array substrate further includes a common electrode with a plurality of slits; and
the common electrode is on a side of the pixel electrode away from the base substrate.

Optionally, an orthographic projection of the common electrode on the base substrate at least partially overlaps with an orthographic projection of the pixel electrode on the base substrate.

Optionally, the array substrate further includes a metal layer on a side of the common electrode close to the base substrate; and
an orthographic projection of the metal layer on the base substrate falls on an edge of an orthographic projection of the pixel electrode on the base substrate.

Optionally, the metal layer is electrically connected to the common electrode.

Optionally, the metal layer is embedded in the common electrode.

Optionally, a groove is formed at a connection position between the pixel electrode and the second source; the array substrate further includes a spacer; and
the spacer is embedded in the groove.

Optionally, the array substrate further includes a first gate contact electrode and a first gate transfer electrode electrically connected to each other;
the first gate contact electrode is in a same layer as the first gate; and
the first gate transfer electrode is in a same layer as the first source and the first drain.

Optionally, the array substrate further includes a second gate contact electrode and a second gate transfer electrode electrically connected to each other;
the second gate contact electrode is in a same layer as the second gate; and
the second gate transfer electrode is in a same layer as the second drain.

Optionally, the oxide thin film transistor further includes a light shielding layer on a side of the oxide semiconductor layer close to the base substrate; and
an orthographic projection of the light shielding layer on the base substrate covers an orthographic projection of a channel of the oxide semiconductor layer on the base substrate.

Optionally, the light shielding layer is in a same layer as the first gate.

In a second aspect, an embodiment of the present disclosure provide a display apparatus, including the array substrate described above.

Optionally, the display apparatus is a virtual reality display apparatus or an augmented reality display apparatus.

Optionally, the virtual reality display apparatus or the augmented reality display apparatus has a pixel resolution greater than or equal to 1500 PPI.

In a third aspect, an embodiment of the present disclosure provides a method of manufacturing an array substrate, including:
sequentially forming a low temperature polycrystalline silicon semiconductor layer, a first gate, an oxide semiconductor layer, and a second gate on a base substrate;
forming a first via and a second via communicated with the low temperature polycrystalline silicon semiconductor layer, through one patterning process;
forming a third via communicated with the oxide semiconductor layer, through one patterning process; and
forming a first source, a first drain and a second drain, such that the first source is electrically connected to the low temperature polycrystalline silicon semiconductor layer through the first via, the first drain is electrically connected to the low temperature polycrystalline silicon semiconductor layer through the second via, and the second drain is electrically connected to the oxide semiconductor layer through the third via.

Optionally, subsequent to the forming the first source, the first drain and the second drain, the method further includes:
forming a fourth via communicated with the oxide semiconductor layer, through one patterning process; and
forming a second source on a side of the second drain away from the base substrate, such that the second source is electrically connected to the oxide semiconductor layer through the fourth via.

### BRIEF DESCRIPTION OF DRAWINGS

FIG. 1 is a schematic diagram illustrating a structure of an exemplary array substrate;

FIG. 2 is a schematic diagram illustrating a structure of an array substrate according to an embodiment of the present disclosure;

FIG. 3 is a schematic diagram illustrating a structure of an array substrate according to an embodiment of the present disclosure;

FIG. 4 is a schematic flow chart illustrating a method of manufacturing an array substrate according to an embodiment of the present disclosure; and

FIGS. 5a to 5k are schematic diagrams of intermediate structures corresponding to respective steps in a method of manufacturing an array substrate according to an embodiment of the present disclosure.

### DETAIL DESCRIPTION OF EMBODIMENTS

In order to enable one of ordinary skill in the art to better understand the technical solutions of the present disclosure, the present disclosure will be further described in detail below with reference to the accompanying drawings and specific embodiments.

Unless defined otherwise, technical or scientific terms used herein shall have the ordinary meaning as understood by one of ordinary skill in the art to which this disclosure belongs. The use of “first”, “second”, and the like in the present disclosure is not intended to indicate any order, quantity, or importance, but rather serves to distinguish one element from another. Also, the term “a”, “an”, “the” or the like does not denote a limitation of quantity, but rather denotes the presence of at least one. The word “comprising”, “comprises”, or the like means that the element or item preceding the word includes the element or item listed after the word and its equivalent, but does not exclude other elements or items. The term “connected”, “coupled” or the like is not restricted to physical or mechanical connections, but may include electrical connections, whether direct or indirect. The terms “upper”, “lower”, “left”, “right”, and the like are used only to indicate relative positional relationships, and when the absolute position of the object being described is changed, the relative positional relationships may also be changed accordingly.

The thin film transistor used in the embodiments of the present disclosure may alternatively be a field effect transistor or other devices with the same characteristics, and since the source and the drain of the transistor used are symmetrical to each other, there is no difference between the source and the drain in terms of functions thereof. In addition, the transistor may be an N-type transistor or a P-type transistor according to the characteristics of the transistor, and in the following embodiments, the N-type transistor is used for explanation. Where an N-type transistor is used, a source and a drain are put through when a high-level signal is input to a gate. The P-type is opposite to this. It should be understood that implementation with P-type transistors will be easily contemplated by one of ordinary skill in the art without inventive effort, and therefore is within the scope of the embodiments of the present disclosure.

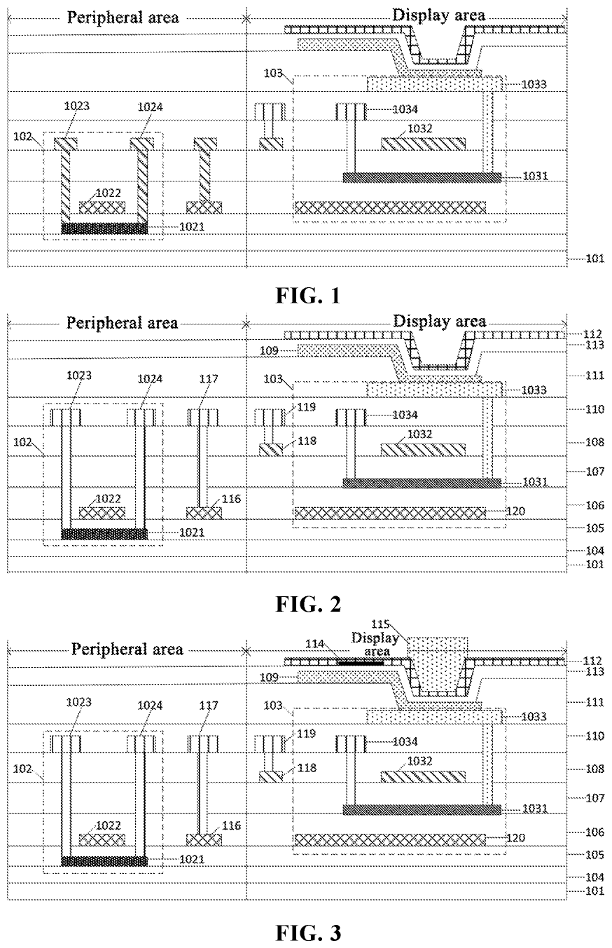

FIG. 1 is a schematic diagram illustrating a structure of an exemplary array substrate. As shown in FIG. 1, the array substrate has a display area and a peripheral area located on a side of the display area. The peripheral area may be located on a left side of the display area or on a right side of the display area, and the peripheral area located on the left side of the display area will be described as an example in the following description. The array substrate includes a base substrate 101, at least one low temperature polysilicon thin film transistor 102 located on the base substrate 101 and arranged in the peripheral area, and at least one oxide thin film transistor 103 located on the base substrate 101 and arranged in the display area. The low temperature polysilicon thin film transistors 102 in the peripheral area may form a gate driving circuit, the oxide thin film transistors 103 in the display area may form a pixel driving circuit, and the gate driving circuit may provide a scanning signal for the pixel driving circuit, which cooperates with a pixel signal and a common signal to drive liquid crystal molecules of a liquid crystal layer to deflect, thereby realizing a display function. It may be understood that the specific structures of the gate driving circuit and the pixel driving circuit may be the same as the structures of circuits in the related art, and will not be described in detail herein.

The low temperature polysilicon thin film transistor 102 includes: a low temperature polysilicon semiconductor layer 1021, a first gate 1022, and a first source 1023 and a first drain 1024, which are sequentially arranged along a direction away from the base substrate 101. The oxide thin film transistor 103 includes: an oxide semiconductor layer 1031, a second gate 1032, and a second source 1033 and a second drain 1034, which are sequentially arranged along the direction away from the base substrate 101.

In order to avoid the mutual influence between the low temperature polysilicon semiconductor layer 1021 of the low temperature polysilicon thin film transistor 102 and the oxide semiconductor layer 1031 of the oxide thin film transistor 103 in the manufacturing process, generally the low temperature polysilicon semiconductor layer 1021 and the oxide semiconductor layer 1031 are located in different layers, respectively, and the low temperature polysilicon semiconductor layer 1021 is formed first, and then the oxide semiconductor layer 1031 is formed. That is, the oxide semiconductor layer 1031 may be located on a side of the low temperature polysilicon semiconductor layer 1021 away from the base substrate 101. Meanwhile, an insulating layer, such as a buffer layer, a gate insulating layer, an interlayer insulating layer, a planarization layer, a passivation layer, or the like, is further arranged between respective adjacent conductive layers, to prevent a short circuit occurring between two adjacent conductive layers.

The first source 1023 and the first drain 1024 of the low temperature polysilicon thin film transistor 102 are connected to two ends of the low temperature polysilicon semiconductor layer 1021 through a first via and a second via penetrating through the insulating layer, respectively. When a control signal (for example, a high level signal) is input to the first gate 1022, the low temperature polysilicon semiconductor layer 1021 is turned on, so that an electrical signal can be transmitted between the first source 1023 and the first drain 1024. Similarly, the second source 1033 and the second drain 1034 in the oxide thin film transistor 103 are connected to two ends of the oxide semiconductor layer 1031 through a third via and a fourth via penetrating through the insulating layer, respectively.

In addition, in order to reduce the process steps, the first source 1023 and the first drain 1024 of the low temperature polysilicon thin film transistor 102 are arranged in the same layer as the second gate 1032 of the oxide thin film transistor 103, and may be formed through the same manufacturing process using the same material. If the first source 1023, the first drain 1024 and the second gate 1032 are all made of metal with a small slope angle, such as molybdenum (Mo), the sheet resistance thereof is large, so that the resistance of the wiring in the peripheral area is large, which is prone to cause the problem of distortion of the display image due to signal delay. If the first source 1023, the first drain 1024, and the second gate 1032 are all made of a metal with a small sheet resistance, such as a three-layer structure composed of titanium/aluminum/titanium (Ti/Al/Ti) alloy, the slope angle thereof is large, so that a trench is prone to be formed near the second gate 1032, and when the second source 1033 and the second drain 1034 of the oxide thin film transistor 103 are formed, a metal material of the second drains 1034 of adjacent oxide thin transistors 103 is prone to remain at the position of the trench, which causes a short circuit occurring between the second drains 1034 of the adjacent oxide thin transistors 103, thereby affecting the display performance.

In order to solve at least one of the above technical problems, embodiments of the present disclosure provide an array substrate, a method of manufacturing the array substrate, and a display apparatus, which will be further described in detail below with reference to the accompanying drawings and specific embodiments.

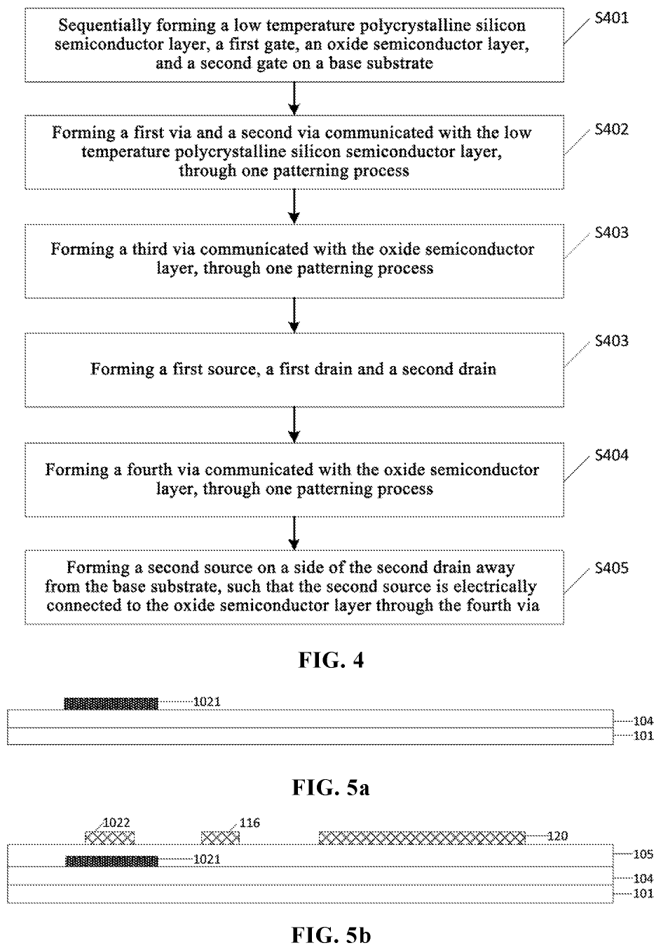

In a first aspect, an embodiment of the present disclosure provides an array substrate. FIG. 2 is a schematic diagram illustrating a structure of an array substrate according to an embodiment of the present disclosure. As shown in FIG. 2, the array substrate has a display area and a peripheral area located on a side of the display area. The array substrate includes: a base substrate 101, at least one low temperature polysilicon thin film transistor 102 located on the base substrate 101 and arranged in the peripheral area, and at least one oxide thin film transistor 103 located on the base substrate 101 and arranged in the display area. The low temperature polysilicon thin film transistor 102 includes: a low temperature polysilicon semiconductor layer 1021, a first gate 1022, and a first source 1023 and a first drain 1024, which are sequentially arranged along a direction away from the base substrate 101. The oxide thin film transistor 103 includes: an oxide semiconductor layer 1031, a second gate 1032, and a second source 1033 and a second drain 1034, which are sequentially arranged along the direction away from the base substrate 101. The first source 1023 and the first drain 1024 are each arranged in a different layer from the second gate 1032.

The base substrate 101 may be made of a rigid material such as glass, which can improve the carrying capacity of the base substrate 101 for other film layers on the base substrate 101. Alternatively, the base substrate 101 may be made of a flexible material such as Polyimide (PI), which can improve the overall bending resistance and tensile resistance of the metal oxide thin film transistor, and prevent the base substrate 101 from being broken due to the stress generated during bending, stretching, and twisting, which results in a defect of open circuit. In practical applications, the material of the base substrate 101 may be selected reasonably according to actual requirements, so as to ensure that the metal oxide thin film transistor has good performance.

It may be understood that a buffer layer 104 may be further arranged on the base substrate 101. The buffer layer 104 may be made of at least one of silicon nitride (SiN) and silicon oxide (SiO2), and may form a single-layer structure made of a single material, or may alternatively form a multi-layer structure made of a plurality of different materials. A film layer in contact with the low temperature polycrystalline silicon semiconductor layer 101 is a SiO2 layer, which may have a thickness in a range of 100 angstroms (Å) to 1500 angstroms, in order to prevent gases such as water and oxygen from intruding into other film layers on the SiO2 layer and causing damage to the array substrate.

The low temperature polysilicon semiconductor layer 1021 may be arranged on the buffer layer 104 in the peripheral area, and may be made of an amorphous silicon material, which is converted into a polysilicon material through a process such as laser annealing. The amorphous silicon material may be specifically at least one of silicon (Si), germanium (Ge), and carbon (C), and may form a single-layer structure made of a single material, or may alternatively form a multi-layer structure made of a plurality of different materials.

A first gate insulating layer 105 may be further arranged on the low temperature polysilicon semiconductor layer 1021. The first gate insulating layer 105 may be made of at least one of silicon nitride (SiN) and silicon oxide (SiO2), and may form a single-layer structure made of a single material, or may alternatively form a multi-layer structure made of multiple different materials. A film layer in contact with the low temperature polysilicon semiconductor layer 1021 is a SiO2 layer, which may protect the low temperature polysilicon layer 1021 and prevent a short circuit from occurring between the low temperature polysilicon layer 1021 and film layers such as the first gate 1022 on the low temperature polysilicon layer 1021.

The first gate 1022 may be arranged on the first gate insulating layer 105. The first gate 1022 may be made of a material with a small slope angle, such as molybdenum (Mo), and the formed slope angle of the first gate 1022 is small, which may facilitate deposition of other film layers on the first gate 1022, and avoid forming a large step difference, which affects the stability of other film layers. Meanwhile, since the slope angle is small, when other film layers are formed, the film layer is stripped in the patterning process, and redundant residues of the film layer material are avoided.

A first interlayer insulating layer 106 may be further arranged on the first gate 1022. The first interlayer insulating layer 106 may be made of at least one of silicon nitride (SiN) and silicon oxide (SiO2), and may form a single-layer structure made of a single material, or alternatively may form a multi-layer structure made of a plurality of different materials. A thickness of the first interlayer insulating layer 106 may be in a range of 1000 Å to 6000 Å. The first interlayer insulating layer 106 can prevent a short circuit from occurring between the first gate 1022 and other film layers on the first gate 1022.

The oxide semiconductor layer 1031 may be arranged on the first interlayer insulating layer 106 in the display area. The oxide semiconductor layer 1031 may be made of at least one of Indium Gallium Zinc Oxide (IGZO), Indium Gallium Tin Oxide (IGTO), and Indium Tin Zinc Oxide (ITZO), which may allow the oxide thin film transistor 103 to have a small leakage current.

A second gate insulating layer 107 is further arranged on the oxide semiconductor layer 1031. The second gate insulating layer 107 may be made of at least one of silicon nitride (SiN) and silicon oxide (SiO2), and may form a single-layer structure made of a single material, or alternatively may form a multi-layer structure made of multiple different materials. The second gate insulating layer 107 can protect the oxide semiconductor layer 1031 and prevent a short circuit from occurring between the oxide semiconductor layer 1031 and film layers, such as a second gate 1032, on the oxide semiconductor layer 1031.

The second gate 1032 may be arranged on the second gate insulating layer 107. The second gate 1032 may be made of a material with a small slope angle, such as molybdenum (Mo), and the formed second gate 1032 has a small slope angle, which may facilitate deposition of other film layers on the second gate 1032, and prevent a large step difference from being formed, which affects the stability of other film layers. Meanwhile, since the slope angle is small, when other film layers are formed, the film layer is stripped off in the patterning process, and redundant residues of the film layer material are avoided.

A second interlayer insulating layer 108 may be further arranged on the second gate 1032. The second interlayer insulating layer 108 may be made of at least one of silicon nitride (SiN) and silicon oxide (SiO2), and may form a single-layer structure made of a single material, or alternatively may form a multi-layer structure made of a plurality of different materials. A thickness of the second interlayer insulating layer 108 may be in a range of 1000 Å to 6000 Å. The second interlayer insulating layer 108 may prevent a short circuit from occurring between the second gate 1032 and other film layers on the second gate 1032.

The first source 1023, the first drain 1024, and the second drain 1034 may be arranged on the second interlayer insulating layer 108. The first source 1023 may be electrically connected to the low temperature polysilicon semiconductor layer 1021 through a first via penetrating through the first gate insulating layer 105, the first interlayer insulating layer 106, the second gate insulating layer 107, and the second interlayer insulating layer 108. The first drain 1024 may be electrically connected to the low temperature polysilicon semiconductor layer 1021 through a second via penetrating through the first gate insulating layer 105, the first interlayer insulating layer 106, the second gate insulating layer 107, and the second interlayer insulating layer 108. The second drain 1034 may be electrically connected to the oxide semiconductor layer 1031 through a third via penetrating through the second gate insulating layer 107 and the second interlayer insulating layer 108.

The first source 1023, the first drain 1024, and the second drain 1034 may be made of the same material and through the same manufacturing process. Specifically, the first source 1023, the first drain 1024, and the second drain 1034 may be all made of a three-layer structure composed of titanium/aluminum/titanium (Ti/Al/Ti) alloy, which has a relatively small resistance, so that the resistance of the wiring in the peripheral area can be ensured to be relatively small, and signal delay can be avoided.

As can be seen from the above description, in the array substrate according to the embodiment of the present disclosure, the first source 1023 and the first drain 1024 of the low temperature polysilicon thin film transistor 102 may be arranged in a different layer from the second gate 1032 of the oxide thin film transistor 103, so that the first source 1023 and the first drain 1024 of the low temperature polysilicon thin film transistor 102 and the second gate 1032 of the oxide thin film transistor 103 do not affect each other, and may be made through different processes and with different materials. For example, the low temperature polysilicon thin film transistor 102 may be made of a material with a relatively small resistance, which may ensure that the resistance of the wiring in the peripheral area is relatively small, and avoid signal delay, thereby improving the display effect of the array substrate. Meanwhile, the second gate 1032 of the oxide thin film transistor 103 may be made of a material with a small slope angle, which may facilitate deposition of the second source 1033 and the second drain 1034 on the second gate 1032, and avoid forming a large step difference, which affects the stability of the oxide thin film transistor 103. Meanwhile, since the slope angle is small, when the second drain 1034 is formed, the film layer is easily stripped off in the patterning process, which prevents a short circuit from occurring between the second drains 1034 of the adjacent oxide thin film transistors 103 due to the redundant residues of the film layer material.

In some embodiments, as shown in FIG. 2, the second source 1033 and the second drain 1034 are arranged in different layers.

In the array substrate with high pixel resolution, the second source 1033 and the second drain 1034 of the oxide thin film transistor 103 may be arranged in different layers, and an insulating layer may be arranged between the second source 1033 and the second drain 1034, so that a sufficient space may be provided between the second source 1033 and the second drain 1034, which prevents a short circuit from occurring between the second source 1033 and the second drain 1034 in the same film layer due to a small distance therebetween, and therefore the stability of the oxide thin film transistor 103 may be improved. Meanwhile, it is not necessary to set a large distance between the second source 1033 and the second drain 1034, so that the space occupied by the oxide thin film transistor 103 can be reduced, and the requirement on the high-pixel-resolution array substrate can be met. In particular, the second source 1033 may be located on a side of the second drain 1034 away from the base substrate 101. The second source 1033 and the second drain 1034 may be made of a three-layer structure composed of titanium/aluminum/titanium (Ti/Al/Ti) alloy, which has a relatively small resistance, so that the resistance of the wiring in the peripheral area can be ensured to be relatively small, and signal delay can be avoided, thereby improving the display effect of the array substrate.

In some embodiments, the array substrate further includes a pixel electrode 109. The pixel electrode 109 is located on a side of the second source 1033 away from the base substrate 101, and is electrically connected to the second source 1033.

A first passivation layer 110 may be further arranged on the second drain 1034. The first passivation layer 110 may be made of at least one of silicon nitride (SiN) and silicon oxide (SiO2), and may form a single-layer structure made of a single material, or alternatively may form a multi-layer structure made of a plurality of different materials. The first passivation layer 110 may prevent a short circuit from occurring between the second source 1033 and the second drain 1034.
a planarization layer 111 may be further arranged on the second source 1033. The planarization layer 111 may be made of an organic material such as acryl, resin, polyimide, or benzocyclobutene, which may be specifically selected according to actual requirements. The planarization layer 111 can planarize the second source 1033 to form a relatively flat surface for facilitating the adhesion of other film layers on the planarization layer 111. In addition, due to the existence of the planarization layer 111, a distance between the second source 1033 and other conductive film layers in the oxide thin film transistor 103 can be increased, and parasitic capacitance generated between the second source 1033 and other conductive film layers on the second source 1033 can be avoided.

The pixel electrode 109 may be arranged on the planarization layer 111. The pixel electrode 109 may be made of a transparent conductive material such as Indium Tin Oxide (ITO), to prevent the pixel electrode 109 from shielding light, thereby improving the overall light transmittance of the array substrate. The pixel electrode 109 may be electrically connected to the second source 1033 of the oxide thin film transistor 103 through a fourth via penetrating through the planarization layer 111, to input a data signal using the oxide thin film transistor 103.

In some embodiments, as shown in FIG. 2, the array substrate further includes a common electrode 112 provided with a plurality of slits. The common electrode 112 is located on a side of the pixel electrode 109 away from the base substrate 101.

A second passivation layer 113 may be further arranged on the pixel electrode 109. The second passivation layer 113 may be made of at least one of silicon nitride (SiN) and silicon oxide (SiO2), and may form a single-layer structure made of a single material, or alternatively may form a multi-layer structure made of a plurality of different materials. The second passivation layer 113 may prevent a short circuit from occurring between the pixel electrode 109 and the common electrode 112.

The common electrode 112 may be arranged on the second passivation layer 113. The common electrode 112 may be made of a transparent conductive material such as Indium Tin Oxide (ITO), to prevent the common electrode 112 from shielding light, so as to improve the overall light transmittance of the array substrate.

Specifically, an orthographic projection of the common electrode 112 on the base substrate 101 at least partially overlaps an orthographic projection of the pixel electrode 109 on the base substrate 101. In practical applications, the pixel electrode 109 may transmit a data signal, and the common electrode 112 may transmit a common signal. The data signal and the common signal may form a driving electric field at positions of the slits, to control the liquid crystal molecules in the liquid crystal layer to deflect, so that light transmits through the liquid crystal layer to realize a display function.

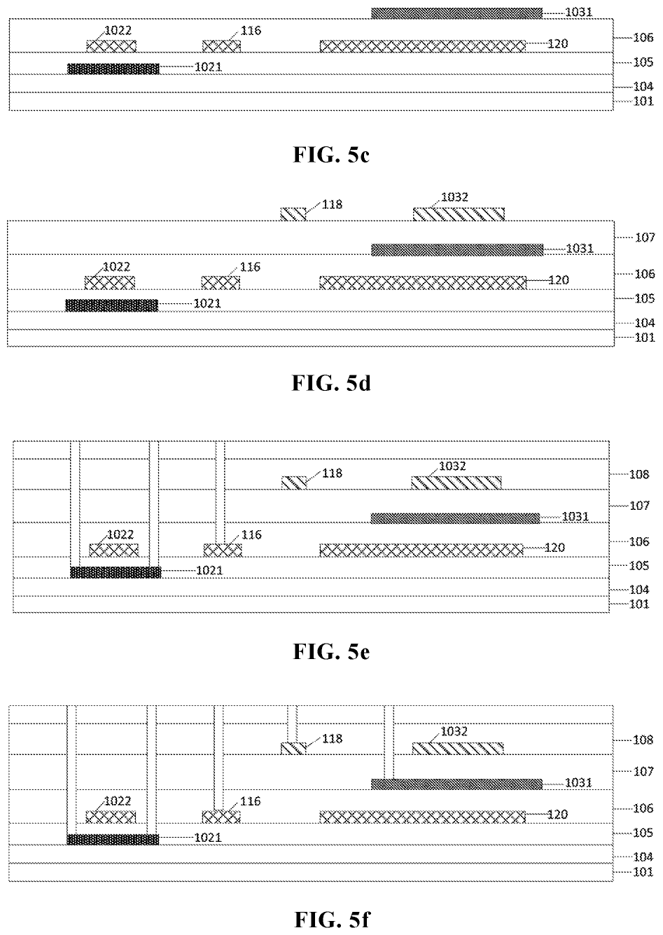

FIG. 3 is a schematic diagram illustrating a structure of another array substrate according to an embodiment of the present disclosure. In some embodiments, as shown in FIG. 3, the array substrate further includes a metal layer 114 on a side of the common electrode 112 close to the base substrate 101. An orthographic projection of the metal layer 114 on the base substrate 101 falls on an edge of an orthographic projection of the pixel electrode 109 on the base substrate 101.

The metal layer 114 may be made of the same metal material as the first gate 1022 or the same metal material as the first source 1023 and the first drain 1024, and has a shielding effect on light, so that crosstalk of light in adjacent pixel units in the array substrate can be prevented, and the display effect of the array substrate can be improved. Meanwhile, the metal layer 114 is electrically connected to the common electrode 112, so that a load of the common electrode 112 can be reduced, the recovery capability of the common signal can be improved, the common signal can be transmitted to the metal layer 114, static electricity is prevented from being accumulated due to suspension of the metal layer 114, and the influence of the static electricity on the stability of the array substrate is avoided.

In some embodiments, as shown in FIG. 3, the metal layer 114 is embedded in the common electrode 112.

The metal layer 114 may be directly embedded into the common electrode 112, so that the metal layer 114 may be directly connected to the common electrode 112, an increase of contact resistance between the metal layer 114 and the common electrode 112 due to connection through a via or the like is avoided, meanwhile, the process steps can be simplified, the process cost is saved, and the thickness of the array substrate can be reduced.

In some embodiments, as shown in FIG. 3, a groove is formed at a connection position between the pixel electrode 109 and the second source 1033. The array substrate further includes a spacer 115, which is embedded in the groove.

The spacer 115 may be made of an organic material having a certain hardness, such as polyacrylic resin or polyester resin. The pixel electrode 109 and the second source 1033 are connected together through a via penetrating through the planarization layer 111. The groove may be formed at the position of the via, the spacer 115 may be embedded in the groove, it is not necessary to perform planarization processing on the position by means of a filling material, and an occupation space may be provided for the spacer 115 to prevent the spacer 115 from sliding down to damage other display devices.

In some embodiments, as shown in FIGS. 2 and 3, the array substrate further includes a first gate contact electrode 116 and a first gate transfer electrode 117 electrically connected to each other. The first gate contact electrode 116 is arranged in the same layer as the first gate 1022. The first gate transfer electrode 117 is arranged in the same layer as the first source 1023 and the first drain 1024.

In practical applications, a signal line, for example, a signal line connected to a signal output terminal of the gate driving circuit, is generally arranged in a film layer where the first source 1023 is located. The first gate contact electrode 116 and the first gate transfer electrode 117, which are electrically connected to each other, can transmit a signal (for example, a scanning signal) in the signal line to the first gate 1021 to control on and off of the low temperature polysilicon thin film transistor 102. The first gate contact electrode 116 and the first gate 1022 may be arranged in the same layer, and both may be made of the same material and through the same manufacturing process, so as to simplify the process steps and save the manufacturing cost. Similarly, the first gate transfer electrode 117 may be arranged in the same layer as the first source 1023 and the first drain 1024, so as to simplify the process steps and save the manufacturing cost.

In some embodiments, as shown in FIGS. 2 and 3, the array substrate further includes a second gate contact electrode 118 and a second gate transfer electrode 119 electrically connected to each other. The second gate contact electrode 118 is arranged in the same layer as the second gate 1032. The second gate transfer electrode 119 is arranged in the same layer as the second drain 1034.

The second gate contact electrode 118 and the second gate transfer electrode 119 are arranged in a manner similar to that of the first gate contact electrode 116 and the first gate transfer electrode 117, respectively. The implementation principle and the beneficial effects thereof may refer to the above description, and are not described herein again.

In some embodiments, as shown in FIGS. 2 and 3, the oxide thin film transistor 103 further includes a light shielding layer 120 located on a side of the oxide semiconductor layer 1031 close to the base substrate 101. An orthographic projection of the light shielding layer 120 on the base substrate 101 covers an orthographic projection of a channel of the oxide semiconductor layer 1031 on the base substrate 101.

The light shielding layer 103 shields light, and can prevent the light from irradiating the channel of the oxide semiconductor layer 1031 from a side of the base substrate 101, so as to protect the oxide semiconductor layer 1031, and prevent the light from affecting the performance of the oxide semiconductor layer 1031, to improve the stability of the oxide thin film transistor 103.

In some embodiments, the light shielding layer 120 is arranged in the same layer as the first gate 1022.

In practical applications, the light shielding layer 120 and the first gate 1022 are made of the same material and formed through the same manufacturing process, so as to simplify the process steps and save the manufacturing cost.

In a second aspect, an embodiment of the present disclosure provides a display apparatus, which includes the array substrate according to any one of the above embodiments. In particular, the display apparatus may be a virtual reality display apparatus or an augmented reality display apparatus, and the pixel resolution of the display apparatus is greater than or equal to 1500 PPI, so as to realize high resolution display, and meet users' requirement for a high resolution display. It should be noted that the implementation principle and the beneficial effects of the display apparatus according to the embodiment of the present disclosure are the same as those of the array substrate according to any one of the embodiments described above, and are not described herein again.

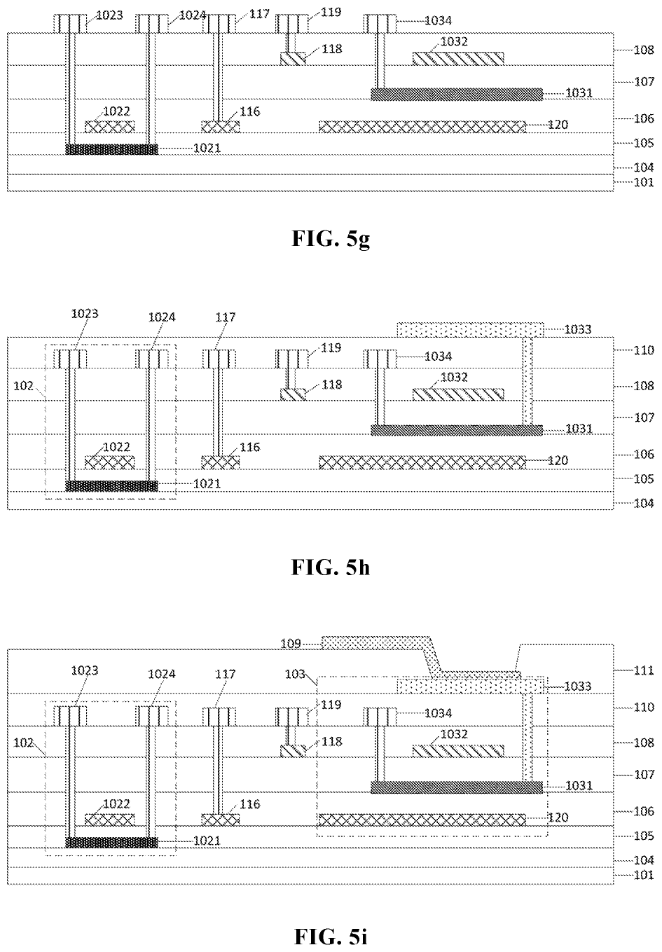

In a third aspect, an embodiment of the present disclosure provides a method of manufacturing an array substrate. FIG. 4 is a schematic flow chart illustrating a method of manufacturing an array substrate according to an embodiment of the present disclosure. As shown in FIG. 4, the method of manufacturing an array substrate includes the following steps S401 to S404.
S401, sequentially forming a low temperature polycrystalline silicon semiconductor layer, a first gate, an oxide semiconductor layer, and a second gate on a base substrate.
S402, forming a first via and a second via communicated with the low temperature polycrystalline silicon semiconductor layer, through one patterning process.
S403, forming a third via communicated with the oxide semiconductor layer, through one patterning process.
S404, forming a first source, a first drain and a second drain, such that the first source is electrically connected to the low temperature polycrystalline silicon semiconductor layer through the first via, the first drain is electrically connected to the low temperature polycrystalline silicon semiconductor layer through the second via, and the second drain is electrically connected to the oxide semiconductor layer through the third via.
S405, forming a fourth via communicated with the oxide semiconductor layer, through one patterning process.
S406, forming a second source on a side of the second drain away from the base substrate, such that the second source is electrically connected to the oxide semiconductor layer through the fourth via.

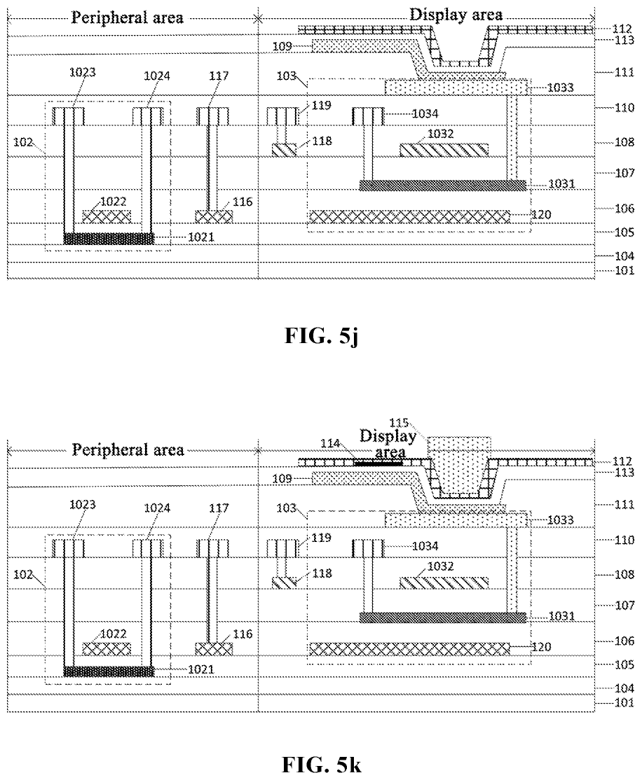

FIGS. 5a to 5k are schematic diagrams of intermediate structures corresponding to respective steps in a method of manufacturing an array substrate according to an embodiment of the present disclosure. The method of manufacturing an array substrate according to the embodiment of the present disclosure will be further described in detail below with reference to diagrams of the intermediate structures at the respective steps.

As shown in FIG. 5a, on a base substrate 101, a film of a buffer layer 104 is formed together with a film of amorphous silicon (a-Si), and then the amorphous silicon (a-Si) is converted into polysilicon (P—Si) through a crystallization process such as laser irradiation and annealing, and then a mask process and a dry etching process are performed to form a pattern of a channel of the low temperature polysilicon semiconductor layer 1021 of the low temperature polysilicon thin film transistor 102 in the peripheral area.

As shown in FIG. 5b, subsequent to forming the channel of the low temperature polysilicon semiconductor layer 1021, a film of the first gate insulating layer 105 is formed, and no mask is required for forming the film of the first gate insulating layer 105. Then, a film of a first conductive layer is formed, and after a mask process, the first gate 1022 is formed through a wet etching process. Meanwhile, the first gate contact electrode 116 and the light shielding layer 120 may further be formed.

As shown in FIG. 5c, subsequent to forming the first conductive layer, a film of the first interlayer insulating layer 106 is formed, and no mask is required for forming the film of the first interlayer insulating layer 106. Then, a film of the oxide semiconductor layer 1031 is formed, and a pattern of a channel of the oxide semiconductor layer 1031 is formed through a mask process and a dry etching process.

As shown in FIG. 5d, subsequent to forming the channel of the oxide semiconductor layer 1031, a film of the second gate insulating layer 107 is formed, and no mask is required for forming the film of the second gate insulating layer 107. Then, a film of a second conductive layer is formed, and a second gate 1032 is formed through a mask process and a wet etching process. Since the slope angle in the wet etching process is smaller, a good coverage of an upper insulating layer can be ensured, so that the wet etching process is adopted. Meanwhile, a second gate contact electrode 118 may further be formed.

As shown in FIG. 5e, subsequent to forming the second conductive layer, a film of a second interlayer insulating layer 108 is formed, and photoresist is coated on the second interlayer insulating layer 108. Then, a mask process is performed to form a pattern of openings in the film layer in the peripheral area, and then a first etching is performed to form the first via, the second via and the fifth via.

As shown in FIG. 5f, subsequent to forming the vias in the peripheral area, the photoresist is stripped off, and the photoresist is coated again on the entire surface of the second interlayer insulating layer 108. Then, a mask process is performed to form a pattern of openings in the film layer in the display area, and then a second etching is performed to form the third via and the sixth via. At this moment, the vias in the peripheral area are covered and protected by photoresist and may not be damaged. Subsequent to forming the vias in the display area, the photoresist is stripped off.

As shown in FIG. 5g, subsequent to forming the respective vias, a film of a third conductive layer is formed, and the first source 1023, the first drain 1024, the second drain 1034, the first gate transfer electrode 117, and the second gate transfer electrode 119 are formed through a mask process and a dry etching process, such that each electrode is electrically connected to another conductive film layer through the corresponding via.

As shown in FIG. 5h, subsequent to forming the third conductive layer, a film of a first passivation layer 110 is formed, and a fourth via is formed through a mask process and a dry etching process. Then, a film of a fourth conductive layer is formed, and the second source 1033 is formed through a mask process and a wet etching process, such that the second source 1033 is electrically connected to the oxide semiconductor layer 1021 through the fourth via. In order to increase the pixel aperture ratio, the second source 1033 is made of an indium tin oxide film.

As shown in FIG. 5i, subsequent to forming the fourth conductive layer, a film of a planarization layer 111 is formed, and a via is formed through a mask process. Then, a film of the pixel electrode 109 is formed, and the pixel electrode 109 is formed through a mask process and a wet etching process.

As shown in FIG. 5j, subsequent to forming the pixel electrode 109, a film of a second passivation layer 113 is formed, and then a mask process and a dry etching process are performed to form vias in the peripheral area, and since the display area is of a PCI (Pixel layer and Common layer Inversion, i.e., the pixel electrode 109 being under the common electrode 112) structure, it is not necessary to form vias in the display area. Then, a film of the common electrode 112 is formed, and then a mask process and a wet etching process are performed to form the common electrode 112.

As shown in FIG. 5k, in order to take into account both color cross and light leakage, a metal layer 114 may be formed under the common electrode 112, so as to not only eliminate color cross, but also reduce the load of the common electrode 112, thereby improving the recovery capability of the common signal. A layer of spacer 115 is formed on the common electrode 112, and fills the formed groove, so that it is not necessary to perform planarization processing on the position by means of a filling material, and an occupation space may be provided for the spacer 115 to prevent the spacer 115 from sliding down to damage other display devices.

It will be understood that the above embodiments are merely exemplary embodiments adopted to illustrate the principles of the present disclosure, and the present disclosure is not limited thereto. It will be apparent to one of ordinary skill in the art that various modifications and improvements can be made without departing from the spirit and scope of the present disclosure, and such modifications and improvements are also considered to be within the scope of the present disclosure.

1. An array substrate, comprising a display area and a peripheral area on a side of the display area, wherein the array substrate comprises a base substrate, at least one low temperature polycrystalline silicon thin film transistor on the base substrate and in the peripheral area, and at least one oxide thin film transistor on the base substrate and in the display area;
each of the at least one low temperature polycrystalline silicon thin film transistor comprises a low temperature polycrystalline silicon semiconductor layer, a first gate, and a first source and a first drain, which are sequentially arranged along a direction away from the base substrate;
each of the at least one oxide thin film transistor comprises an oxide semiconductor layer, a second gate, and a second source and a second drain, which are sequentially arranged along the direction away from the base substrate; and
the first source and the first drain are each in a different layer from the second gate.

2. The array substrate according to claim 1, wherein the first source and the first drain are each in a same layer as the second drain.

3. The array substrate according to claim 1, wherein the second source and the second drain are in different layers, respectively.

4. The array substrate according to claim 3, wherein the second source is on a side of the second drain away from the base substrate.

5. The array substrate according to claim 1, further comprising a pixel electrode,
wherein the pixel electrode is on a side of the second source away from the base substrate, and is electrically connected to the second source.

6. The array substrate according to claim 5, further comprising a common electrode with a plurality of slits,
wherein the common electrode is on a side of the pixel electrode away from the base substrate.

7. The array substrate according to claim 6, wherein an orthographic projection of the common electrode on the base substrate at least partially overlaps with an orthographic projection of the pixel electrode on the base substrate.

8. The array substrate according to claim 6, further comprising a metal layer on a side of the common electrode close to the base substrate,
wherein an orthographic projection of the metal layer on the base substrate falls on an edge of an orthographic projection of the pixel electrode on the base substrate.

9. The array substrate according to claim 8, wherein the metal layer is electrically connected to the common electrode.

10. The array substrate according to claim 9, wherein the metal layer is embedded in the common electrode.

11. The array substrate according to claim 6, further comprising a groove at a connection position between the pixel electrode and the second source, and a spacer; wherein the spacer is embedded in the groove.

12. The array substrate according to claim 1, further comprising a first gate contact electrode and a first gate transfer electrode electrically connected to each other,
wherein the first gate contact electrode is in a same layer as the first gate; and
the first gate transfer electrode is in a same layer as the first source and the first drain.

13. The array substrate according to claim 1, further comprising a second gate contact electrode and a second gate transfer electrode electrically connected to each other,
wherein the second gate contact electrode is in a same layer as the second gate; and
the second gate transfer electrode is in a same layer as the second drain.

14. The array substrate according to claim 1, wherein the oxide thin film transistor further comprises a light shielding layer on a side of the oxide semiconductor layer close to the base substrate; and
an orthographic projection of the light shielding layer on the base substrate covers an orthographic projection of a channel of the oxide semiconductor layer on the base substrate.

15. The array substrate according to claim 14, wherein the light shielding layer is in a same layer as the first gate.

16. A display apparatus, comprising the array substrate according to claim 1.

17. The display apparatus according to claim 16, wherein the display apparatus is a virtual reality display apparatus or an augmented reality display apparatus.

18. The display apparatus according to claim 17, wherein the virtual reality display apparatus or the augmented reality display apparatus has a pixel resolution greater than or equal to 1500 PPI.

19. A method of manufacturing an array substrate, comprising:
sequentially forming a low temperature polycrystalline silicon semiconductor layer, a first gate, an oxide semiconductor layer, and a second gate on a base substrate;
forming a first via and a second via communicated with the low temperature polycrystalline silicon semiconductor layer, through one patterning process;
forming a third via communicated with the oxide semiconductor layer, through one patterning process; and
forming a first source, a first drain and a second drain, such that the first source is electrically connected to the low temperature polycrystalline silicon semiconductor layer through the first via, the first drain is electrically connected to the low temperature polycrystalline silicon semiconductor layer through the second via, and the second drain is electrically connected to the oxide semiconductor layer through the third via.

20. The method according to claim 19, wherein subsequent to the forming the first source, the first drain and the second drain, the method further comprises:
forming a fourth via communicated with the oxide semiconductor layer, through one patterning process; and
forming a second source on a side of the second drain away from the base substrate, such that the second source is electrically connected to the oxide semiconductor layer through the fourth via.
